(19) United States
(12) Patent Application Publication
(10) Pub. No.: US 2020/0044479 A1
(43) Pub. Date: Feb. 6, 2020

(54) POWER STRIP WITH UNINTERRUPTABLE POWER SUPPLY

(71) Applicant: MOUSA A.M.E. MOHAMMAD, KUWAIT CITY (KW)

(72) Inventor: MOUSA A.M.E. MOHAMMAD, KUWAIT CITY (KW)

(21) Appl. No.: 16/398,162

(22) Filed: Apr. 29, 2019

Related U.S. Application Data
(60) Provisional application No. 62/715,174, filed on Aug. 6, 2018.

(51) Int. Cl. H02J 9/06; H02J 7/00; H02H 9/00; H05K 7/20

(52) U.S. Cl. CPC H02J 9/061; H02J 7/0063; H05K 7/202; H02J 7/0047; H02H 9/005; H02J 7/0042

(57) ABSTRACT

The power strip with an uninterruptable power supply is a multiple outlet power strip with an on-board rechargeable battery for providing an uninterruptable power supply. The power strip with an uninterruptable power supply includes a housing having a recess defined therein for removably receiving a rechargeable battery. A surge suppressor is mounted within the housing and is adapted for connection to an external power supply. A plurality of electrical outlets are mounted to the housing and are each in electrical communication with the surge suppressor for providing power to external electrical loads. The rechargeable battery is in selective electrical communication with both the surge suppressor and the plurality of electrical outlets. In use, the rechargeable battery is selectively charged by a charging current delivered from the surge suppressor. The rechargeable battery also selectively provides auxiliary power to the plurality of electrical outlets when power from the external power supply ceases.

### CROSS-REFERENCE TO RELATED APPLICATION

This application claims the benefit of U.S. Provisional Patent Application No. 62/715,174, filed on Aug. 6, 2018.

### BACKGROUND

### 1. Field

The disclosure of the present patent application relates to electrical appliances, and particularly to a power strip with an uninterruptible power supply that provides a multiple outlet power strip with an on-board rechargeable battery for providing an uninterruptable power supply.

### 2. Description of the Related Art

Power strips provide multiple electrical outlets, which are fed, typically, from only a single electrical outlet. Although power strips are often provided with surge protectors to prevent damage to connected electrical loads in the event of a power surge, power strips are still vulnerable to interruptions in power. In other words, conventional power strips cease to function if the external power supply to which they are connected has an interruption or cessation of power. Given the great utility of conventional power strips, it would obviously be desirable to be able to provide the functionality of a power strip with an additional uninterruptable power supply. Thus, a power strip with an uninterruptable power supply solving the aforementioned problems is desired.

### SUMMARY

The power strip with an uninterruptable power supply is a multiple outlet power strip with an on-board rechargeable battery for providing an uninterruptable power supply. The power strip with an uninterruptable power supply includes a housing having a recess defined therein for removably receiving a rechargeable battery. As in a conventional power strip, a surge suppressor is mounted within the housing and is adapted for connection to an external power supply. A plurality of electrical outlets are mounted to the housing and are each in electrical communication with the surge suppressor for providing power to external electrical loads in a conventional manner. The rechargeable battery is in selective electrical communication with the both the surge suppressor and the plurality of electrical outlets. The plurality of electrical outlets may include at least two separate and distinct types of electrical outlets.

In use, when the rechargeable battery is received and releasably locked within the recess, the rechargeable battery is selectively charged by a charging current delivered from the surge suppressor. Similar to a conventional uninterruptable power supply, the rechargeable battery selectively provides auxiliary power to the plurality of electrical outlets when power from the external power supply ceases.

These and other features of the present disclosure will become readily apparent upon further review of the following specification and drawings.

### BRIEF DESCRIPTION OF THE DRAWINGS

FIG. 1 is a perspective view of a power strip with an uninterruptable power supply as described herein.

FIG. 2 is a perspective view of the power strip of FIG. 1, shown with the battery for the uninterruptible power supply exploded therefrom.

FIG. 3 is another perspective view of the power strip of FIG. 1, shown with the battery for the uninterruptible power supply exploded therefrom.

FIG. 4 is a block diagram of the power strip of FIG. 1.

Similar reference characters denote corresponding features consistently throughout the attached drawings.

### DETAILED DESCRIPTION OF THE PREFERRED EMBODIMENTS

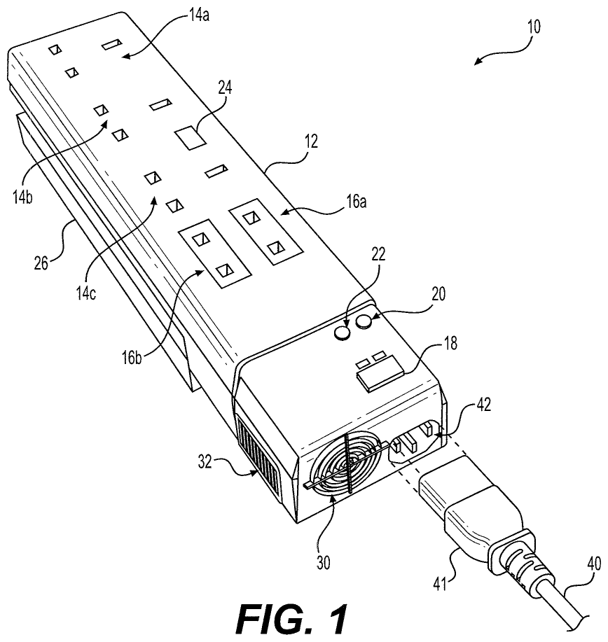

Referring now to FIGS. 1-3, the power strip with an uninterruptable power supply 10 is a multiple outlet power strip with an on-board rechargeable battery 26 for providing an uninterruptable power supply. The power strip with an uninterruptable power supply 10 includes a housing 12 having a recess 50 defined therein for removably receiving the rechargeable battery 26. It should be understood that the overall dimensions and configuration of the housing 12 are shown for exemplary purposes only. Additionally, it should be understood that the housing 12 may be manufactured from any suitable material, such as aluminum, allowing for conductive and convective cooling.

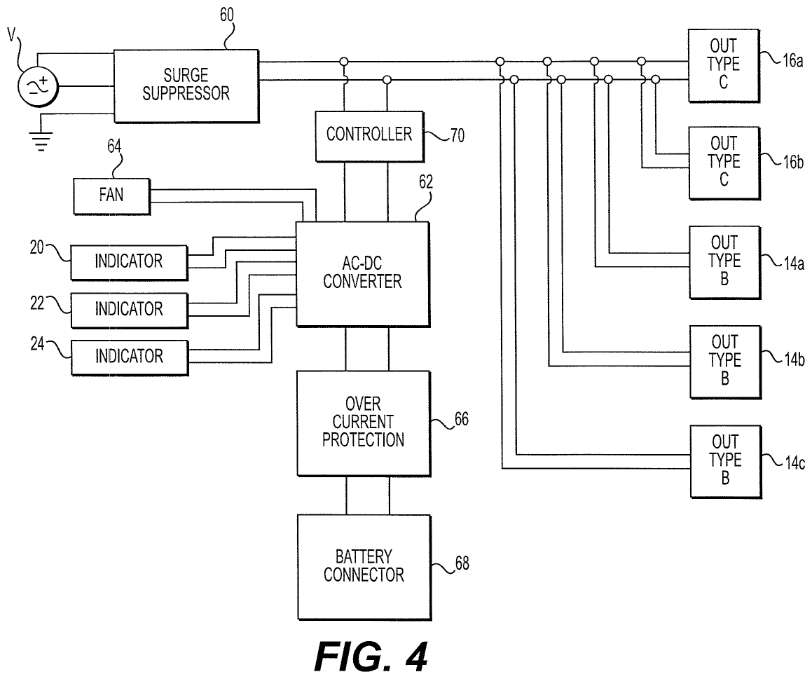

With further reference to FIG. 4, as in a conventional power strip, a surge suppressor 60 is mounted within the housing 12 and is adapted for connection to an external power supply V. For example, as in a conventional power strip, the external power supply V may be an external source of AC power, such as a conventional wall socket or the like. In FIG. 1, a conventional power cord 40, having a conventional head 41 for removable connection with socket 42, is shown. It should be understood that power cord 40 and socket 42 are shown for exemplary purposes only, and that any suitable type of power cord connection for providing power from external power supply V may be used. It should be further understood that the power strip with an uninterruptable power supply 10 may be used with any suitable type of external power source, such as a conventional 120 VAC or 220 VAC power supply.

A plurality of electrical outlets are mounted to the housing 12 and are each in electrical communication with the surge suppressor 60 for providing power to external electrical loads in a conventional manner. In FIG. 1, two separate and distinct types of outlets are shown. Outlets 14a, 14b and 14c are shown as being “type B” outlets, i.e., electrical outlets of the type typically used in the United States of America. Outlets 16a and 16b are shown as being “type C” outlets, which may be commonly found in such countries as Kuwait. It should be understood that the choice of outlets shown in FIG. 1 is for exemplary and illustrative purposes only, and that the plurality of outlets provided may all be of any single type, or may be a combination of any desired types. It should be further understood that the number of outlets is shown for exemplary purposes only.

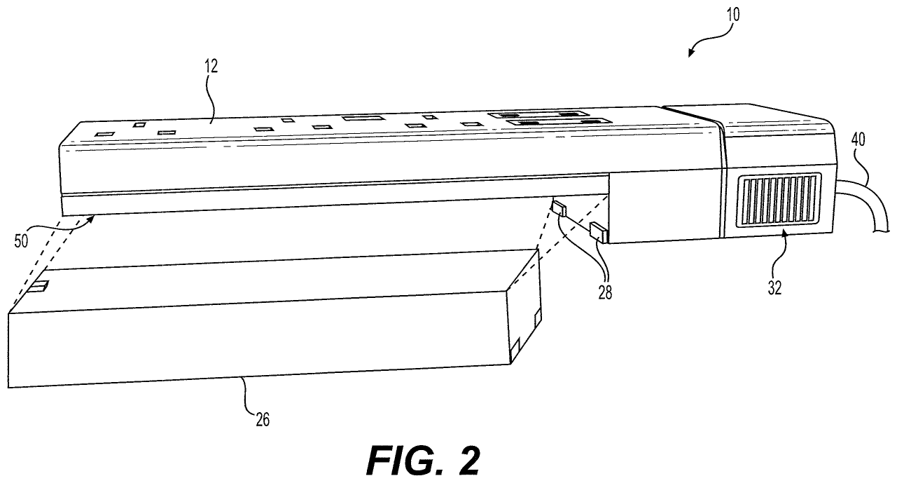

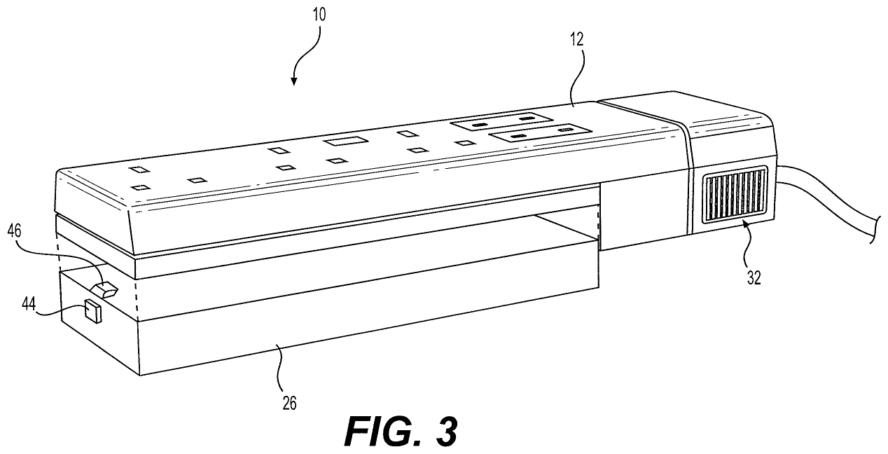

As shown in FIGS. 2 and 3, the rechargeable battery 26 is removably receivable within recess 50. In FIG. 2, exemplary snap connectors 28 can be seen for stabilizing and releasably holding rechargeable battery 26 on one end. As best shown in FIG. 3, on the other end of rechargeable battery 26, a locking member 46 selectively engages with housing 12 through selective actuation of locking button 44. This allows the user to easily remove the rechargeable battery 26 (through pressing of locking button 44) when it is desired to replace, transport or use rechargeable battery 26 for a different purpose. It should be understood that the configuration, overall shape and relative dimensions of rechargeable battery 26 are shown for exemplary purposes only. Additionally, it should be understood that different types of batteries may be provided for different purposes. For example, the rechargeable battery 26 may be switched with a high capacity rechargeable battery when the user is in need of such functionality.

Returning to FIG. 4, the rechargeable battery 26 is in selective electrical communication with the both the surge suppressor 60 and the plurality of electrical outlets 14a, 14b, 14c, 16a, 16b. In use, when the rechargeable battery 26 is received within the recess 50, the rechargeable battery 26 is selectively charged by a charging current delivered from the surge suppressor 60. As in a conventional recharging system, the AC power provided by external power source V is converted to DC power by an AC-DC converter 62. It should be understood that any suitable type of AC-DC converter may be utilized. Additionally, as is well known in the art, an over current protection circuit 66 is provided to prevent overloads, short circuits and ground faults. It should be understood that any suitable type of over current protection circuit may be utilized. The over current protection circuit 66 is in electrical communication with a battery connector 68, which may be any suitable type of connector or leads, such as pogo pins, for electrical connection with the rechargeable battery 26 when the rechargeable battery is connected in recess 50.

Similar to a conventional uninterruptable power supply, the rechargeable battery 26 selectively provides auxiliary power to the plurality of electrical outlets 14a, 14b, 14c, 16a, 16b when power from the external power supply V ceases. Controller 70 is provided for detecting interruption of power from external power supply V. As in a conventional uninterruptable power supply, controller 70 may be any suitable type of processor, controller, simple detection and switching circuit, relay switch or the like. When controller 70 detects an interruption in power from external power supply V, converter 62 switches to convert the DC current provided by rechargeable battery 26 back into AC current, which is then fed, through switching in controller 70, to the plurality of electrical outlets 14a, 14b, 14c, 16a, 16b.

Additionally, as in a conventional uninterruptable power supply, a fan 64 is preferably mounted within housing 12 for cooling the internal circuitry of the power strip with an uninterruptable power supply 10. As shown in FIGS. 1 and 2, a conventional ventilation outlet 30 and a conventional ventilation inlet 32 are provided in housing 12. It should be understood that the overall size, relative dimensions and placement of conventional ventilation outlet 30 and conventional ventilation inlet 32 are shown for exemplary purposes only. Additionally, it should be understood that any suitable type of fan may be utilized.

Further, first, second and third visual indicators 20, 22, 24, respectively, may also be mounted to housing 12. First, second and third visual indicators 20, 22, 24, respectively, may be, for example, light emitting diodes (LEDs). In this example, DC power is provided thereto from AC-DC converter 62. The first visual indicator 20 may provide a visual indication of connection to the external power supply V, the second visual indicator 22 may provide a visual indication of recharging of the rechargeable battery 26, and the third visual indicator 24 may provide a visual indication of connection of at least one of the plurality of electrical outlets 14a, 14b, 14c, 16a, 16b to an external load. Further, as in a conventional power strip, any suitable type of power switch 18 may be provided.

It is to be understood that the power strip with an uninterruptable power supply is not limited to the specific embodiments described above, but encompasses any and all embodiments within the scope of the generic language of the following claims enabled by the embodiments described herein, or otherwise shown in the drawings or described above in terms sufficient to enable one of ordinary skill in the art to make and use the claimed subject matter.

1. A power strip with an uninterruptable power supply, comprising:
a housing having a recess defined therein;
a surge suppressor mounted within the housing, the surge suppressor being adapted for connection to an external power supply;
a plurality of at least two separate and distinct types of electrical outlets mounted to the housing and being in electrical communication with the surge suppressor, wherein the at least two types of electrical outlets include at least type B and type C outlets;
a rechargeable battery removably received within the recess of the housing, the rechargeable battery being in selective electrical communication with the surge suppressor and the plurality of electrical outlets, whereby the rechargeable battery is selectively charged by a charging current delivered from the surge suppressor, and the rechargeable battery selectively provides auxiliary power to the plurality of electrical outlets when power from the external power supply is interrupted; and
at least three visual indicators mounted to the housing for providing visual indication of electrical conditions, wherein the electrical conditions are, respectively, connection to the external power supply, recharging state of the rechargeable battery, and at least one of the plurality of electrical outlets being in electrical communication with an external load.

2-5. (canceled)

6. The power strip with an uninterruptable power supply as recited in claim 1, further comprising an AC-DC converter in electrical communication with the surge suppressor.

7. The power strip with an uninterruptable power supply as recited in claim 6, wherein the AC-DC converter is in selective electrical communication with the rechargeable battery for selectively delivering the charging current thereto.

8. The power strip with an uninterruptable power supply as recited in claim 7, further comprising an over current protection circuit in electrical communication with the AC-DC converter and in selective electrical communication with the rechargeable battery.

9. The power strip with an uninterruptable power supply as recited in claim 1, further comprising a fan mounted in the housing.

10. The power strip with an uninterruptable power supply as recited in claim 1, wherein the rechargeable battery is releasably locked to the housing within the recess.

11-20. (canceled)
